(19) United States
(12) Patent Application Publication
(10) Pub. No.: US 2023/0054335 A1
(43) Pub. Date: Feb. 23, 2023

(54) SYSTEMS AND METHODS FOR FORMING A FLUIDIC SYSTEM

(71) Applicant: Platelet Biogenesis, Inc., Watertown, MA (US)

(72) Inventors: Jorge Luis Valdez Macias, Watertown, MA (US); Marcus Lehmann, Watertown, MA (US); Jonathan N. Thon, Watertown, MA (US); Douglas G. Savin, Watertown, MA (US)

(73) Assignee: Platelet Biogenesis, Inc., Watertown, MA (US)

(21) Appl. No.: 17/891,306

(22) Filed: Aug. 19, 2022

Related U.S. Application Data
(63) Continuation of application No. PCT/US2021/019660, filed on Feb. 25, 2021.
(60) Provisional application No. 62/981,373, filed on Feb. 25, 2020.

(51) Int. Cl. B01L 3/00; B29C 65/16; B29C 65/00

(52) U.S. Cl. CPC B01L 3/502707; B29C 65/1635; B29C 65/1696; B29C 66/1142; B29C 66/244; B01L 2300/0681; B01L 2300/0864; B01L 2300/0887; B01L 2300/0816; B01L 2300/0867

(57) ABSTRACT

There is provided a method of making a fluidic system that comprises assembling a fluidic system comprising a first plate, a second plate and a membrane disposed between the first plate and the second plate; applying laser energy to the fluidic system to cause the first plate, the second plate and the membrane to melt at bonding areas; and allowing the bonding areas to cool down such that the first plate, the second plate and the membrane are bonded together.

### RELATED APPLICATIONS

This application is a U.S. Continuation Application filing under 35 U.S. Code § 111 of International Application No. PCT/US2021/019660, filed Feb. 25, 2021, which claims the benefit of and priority to U.S. Provisional Application Ser. No. 62/981,373, filed on Feb. 25, 2020, the content of which is hereby incorporated by reference in its entirety.

### GOVERNMENT SUPPORT

This invention was made with government support under 1R44HL131050-01 awarded by the National Institutes of Health (NIH) and under BA170091 awarded by the Department of Defense. The government has certain rights in the invention.

### FIELD

The present disclosure generally relates to fluidic systems, and more particularly to bioreactors, and method of manufacturing such bioreactors.

### BACKGROUND OF THE DISCLOSURE

The ability to in vitro manufacture viable three-dimensional cellular biological products that mimic natural tissue or cells (e.g., plasma, platelets, white blood cells, red blood cells) has proven to be very challenging. Current manufacturing methods for the in vitro manufacture of viable three-dimensional cellular biological products are costly, time consuming, and produce systems that are less durable because of their wear and tear.

For example, currently manufactured bioreactors are commonly formed by machining acrylic plates and bonding them together via pressure sensitive adhesive. This method is costly, time consuming and cumbersome to build because even if a small force is pulling the adhered parts of the plates away from each other, the device can delaminate allowing leaks, making it unusable or unreliable as a bioreactor.

Thus, there is a need for improved system and manufacturing methods to not only culture in vitro viable three-dimensional cellular biological products that not only mimics the mechanical environment, but at the same time are durable, are easy to assemble for use, and are cost effective, in providing the desired cellular products (e.g., plasma, platelets, white blood cells, red blood cells).

### SUMMARY OF THE DISCLOSURE

The present system discloses an improved system and manufacturing methods that advantageously applies laser energy at bonding areas in a fluidic system to cause a first plate, a second plate and a membrane to melt at the bonding areas. The bonding areas are allowed to cool down such that the first plate, the second plate and the membrane are bonded together in a manner that prevents the detrimental influence of forces, even if small, to pull the bonding areas apart from each other such that the device will delaminate allowing leaks making it unusable as a bioreactor. In other words, the laser energy, when applied to the bonding areas to bond the first plate, the second plate and the membrane, the laser-based bonding minimizes or eliminates the delamination of the device, thereby enhancing the durability (shelf-life) of the device. Manufacturing of such delamination-proof devices is cost-effective because they have an extended shelf life and can be rapidly assembled, are leak-proof and can be used in bulk quantities.

Thus, in some embodiments, the present disclosure provides a method of making a fluidic system that comprises assembling a fluidic system comprising a first plate, a second plate and a membrane disposed between the first plate and the second plate; applying laser energy to the fluidic system to cause the first plate, the second plate and the membrane to heat at bonding areas; and allowing the bonding areas to cool down such that the first plate, the second plate and the membrane are bonded together.

In some embodiments, the present disclosure provides a method of making a fluidic system that comprises connecting a first plate and a second plater to form a fluidic body, the first plate including a first pattern of ribs and the second plate including a second pattern of ribs corresponding to the first pattern of ribs, such that the first pattern of ribs and the second pattern of ribs are aligned to define a plurality of fluidic lanes through the fluidic body; disposing a membrane between the first plate and the second plate, the membrane separating each of the plurality of fluidic lanes into a first channel and a second channel; and applying laser energy to the fluidic body such that the laser energy is transmitted through the first plate and is absorbed by the second plate at the second pattern of ribs to cause the first plate, the second plate and the membrane to weld with one another to fluidically seal the plurality of fluidic lanes.

In some embodiments, the steps of the instant methods can be performed under vacuum or negative pressure to avoid expansion of gas entrapped within the pores of the membrane from creating cosmetic or functional imperfections as it expands when heated by the laser and subsequently contracts as it cools to room temperature.

In some embodiments, the first plate is light transmitting and the second plate is light absorbing. In some embodiments, the membrane includes a light absorbing layer. In some embodiments, the first plate, the second plate and the membrane are made of the same material. In some embodiments, the first plate and the second plate include a pattern of ribs that form the bonding areas.

In some embodiments, one or more fluid channels are formed in the fluidic system with the membrane being disposed in the one or more fluid channels. In some embodiments, a mask on top of the fluidic system, the mask being configured to block the laser energy from portions of the membrane disposed in the one or more fluid channel. In some embodiments, the first plate and the second plate each include an inlet manifold and outlet manifold to enable fluid flow through one or more fluid channels. In some embodiments, the inlet manifold and the outlet manifold of the second plate are located on a bottom side of the second plate and are formed by a cover coupled to the bottom side of the second plate.

In some embodiments, the present disclosure provides a fluidic system that comprises a first plate configured to transmit light; a second plate configured to absorb light; and a membrane positioned between the first plate and the second plate, wherein the first plate, the second plate and the membrane are laser bonded together at a preselected pattern of bonding areas such that one or more fluid channels are formed in the fluidic system with the membrane being disposed in the one or more fluid channels.

In some embodiments, the first plate, the second plate and the membrane are made of the same material. In some embodiments, the first plate includes a first pattern of ribs and the second plate includes a second pattern of ribs corresponding to the first pattern of ribs, wherein the first pattern of ribs connects to the second pattern of ribs to form the bonding areas. In some embodiments, the first plate and the second plate each include an inlet manifold and outlet manifold to enable fluid flow through one or more fluid channels. In some embodiments, the inlet manifold and the outlet manifold of the second plate are located on a bottom side of the second plate and are formed by a cover coupled to the bottom side of the second plate.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 is an exploded view of an exemplary embodiment of a fluidic system of the present disclosure;

FIG. 2A is a top perspective view of a plate of a fluidic system of the present disclosure;

FIG. 2B is a bottom perspective view of a plate of a fluidic system of the present disclosure;

FIG. 2C is a cross-sectional view of an embodiment of a fluidic system of the present disclosure;

FIG. 3 illustrates an exemplary flowchart of a process of constructing a fluidic system using a welding process according to the present disclosure;

FIGS. 4A and 4B are top views of an embodiment of an upper plate of a fluidic system of the present disclosure;

FIG. 5 is an exploded view of an exemplary embodiment of a fluidic system of the present disclosure;

FIG. 6 is an embodiment of a top mask used in a process of the present disclosure;

FIG. 7A is a cross-sectional view of an embodiment of a fluidic system formed using an a welding technique of the present disclosure;

FIG. 7B is a zoomed in view of the cross-sectional view of the fluidic system shown in FIG. 7A;

FIG. 8 is an exploded view of an exemplary embodiment of a fluidic system of the present disclosure with a light absorbing layer;

FIGS. 9A and 9B illustrate an embodiment of a light absorbing layer of the present disclosure;

FIG. 10 is an exploded view of an exemplary embodiment of a fluidic system of the present disclosure;

FIGS. 11A and 11B illustrate a bottom view of an embodiment of a plate of a fluidic system of the present disclosure;

FIG. 12 is an embodiment of a bottom mask;

FIG. 13A is a cross-sectional view of an embodiment of a fluidic system formed using a welding technique of the present disclosure;

FIG. 13B is a zoomed in view of the cross-sectional view of the fluidic system shown in FIG. 13A; and

FIG. 14 is an image of an embodiment of a plurality of fluidic systems of the present disclosure in a stacked configuration.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The present disclosure provides methods and systems for efficient manufacturing of various fluidic systems for manufacturing biological products, such as bioreactors or filter systems. The present disclosure further provides fluidic systems manufactured by the methods of instant disclosure and methods of their use. In some embodiments, the fluidic systems of the present disclosure can be manufactured using laser welding.

In some embodiments, the fluidic systems of the present disclosure are capable of efficient and scalable production of biological products, such as platelets or non-naturally existing, novel, anucleated platelets or platelet-like cells or platelet variants (collectively referred to as “PLCs” (or in its singular form: “PLC”)) or derivatives thereof that may structurally differ from the bone marrow derived platelets. In some aspects, the present disclosure provides non-natural extracellular vesicles (EVs) that are made in vitro as admixtures with the PLCs. Extracellular vesicles (EVs) comprise microvesicles (MVs) or exosomes or a combination thereof, are smaller in size as compared to PLCs, and are biologically active. Each component in the admixture, i.e., PLCs, microvesicles and exosomes can substantially be isolated into individual components from the admixture, for example based on their size. “Non-natural” as used herein refers to manufactured, created, or constructed by human beings, artificial, or mimicking something that exists in nature.

“Derivatives”, as used herein, refer to genetically engineered PLCs or extracellular vesicles or a combination thereof for therapeutic use, inclusive of PLC precursor cells (e.g., pluripotent stem cells genetically engineered in a manner such that the PLCs or extracellular vesicles produced by these PLC/EV precursor cells produce a molecule of interest in the PLCs or extracellular vesicles or in both, and in any other modification described herein.

“PLC” or “PLCs” or artificial platelets as interchangeably used herein, refer to platelets or platelet like cells structurally differing from naturally existing bone marrow derived platelets (natural counterpart) yet manifesting many of the properties of their natural counterpart. PLCs are also inclusive of derivatives and variants as defined herein.

“Variant” or “Variants” as interchangeably used herein refers to manifesting structural variety, structural deviation, or structural differences between PLCs and donor platelets.

In order to create a biologically compatible device that can be used to generate and collect biological products, the present disclosure provides methods and systems for laser welding of biocompatible materials.

In some embodiments, the present disclosure relates to systems and methods that include a fluidic bioreactor, for example, a millifluidic bioreactor, a microfluidic bioreactor, or collections of such reactors, that can be used to generate biological products/target biological substance from biological source material. In some embodiments, a plurality of bioreactors can be used together, for example in a stacked configuration, to produce an increased yield of a desired cell type. Alternatively, operation of the bioreactors may require coupling with an internal or external cell retention device on a recycle line, by centrifugation, sedimentation, ultrasonic separation or microfiltration with spin-filters, alternating tangential flow (ATF) filtration or tangential flow filtration (TFF).

In some embodiments, the term “biological source material” refers to a biological material that may produce or give rise to another biological material when subjected to shear stress. For example, biological materials can include, but are not limited to, a suspension of cells, for example, induced pluripotent stem cells (iPSCs), human pluripotent stem cells (hPSCs) megakaryocytes, CHO cells, or yeast cells, mammalian cells, eukaryotic or prokaryotic cells, or other biologically active living organisms.

In some embodiments, the term “biological products” refers to a biological product that can result from the biological source material being exposed to shear stress, for example, imparted by the flow rate, as well as nutrient and gas transport being facilitated by the medium flow rate. Biological product can be produced by the biological source material by triggering cytoskeletal changes in response to shear, being extruded from the source material, or allowing secretion of product from the source material. Biological product examples can include, but are not limited to, platelets, PLCs or derivatives thereof, microparticles, micro vesicles, proteins or polypeptides, such as but not limited to antibodies and growth factors, and plasmids.

For example, the present fluidic system can be used to replicate a process that produces platelet like cells. Typically, megakaryocytes generated in the bone marrow move toward and settle onto endothelial cells that line blood vessels. There they extend long, branching cellular structures called proplatelets into the blood vessel space through gaps in the endothelium. Experiencing shear rates due to blood flow, proplatelets extend and release platelets or platelet like cells and/or extracellular vesicles (EVs) into the circulation. For example, proplatelets experience wall shear rates ranging from, 100 to 10,000 s⁻¹ or, more particularly, from 500 to 2500 s⁻¹.

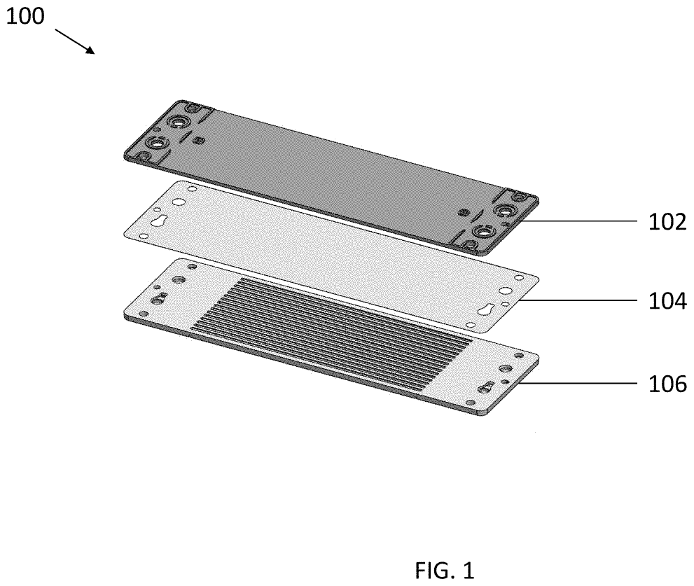

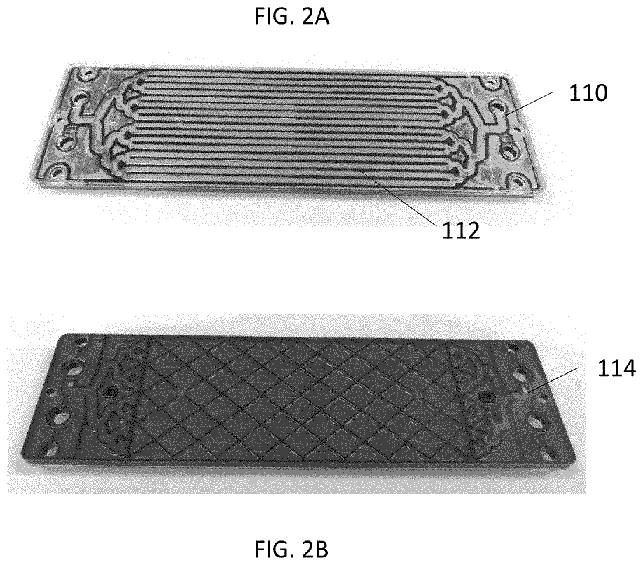

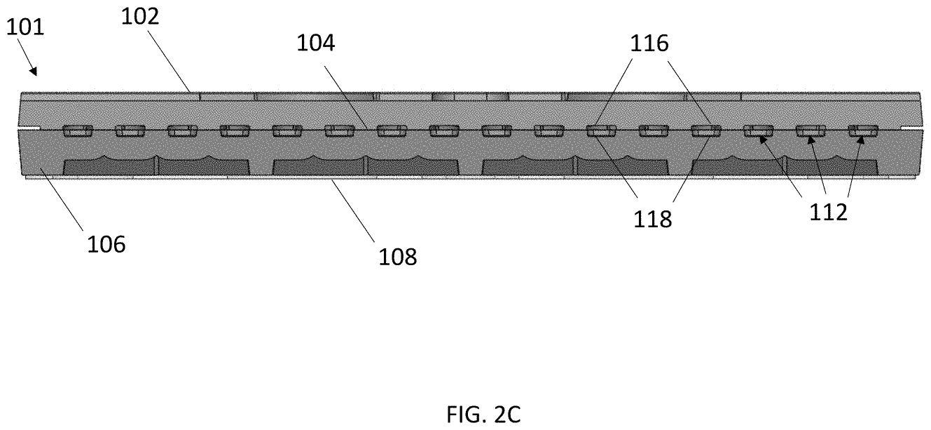

Referring to FIG. 1 and FIGS. 2A-2C, an exemplary fluidic system 100 may include a first plate 102, a second plate 106, and a membrane 104 disposed between the first plate 102 and the second plate 106. In some embodiments, the present fluidic system 100 may further include a cover film 108 disposed on the bottom of the second plate.

When the first plate 102 and the second plate 106 are joined to form a fluidic system body 101 of the fluidic system 100, one or more flow lanes or channels 112 are formed in the fluidic system body 101 to provide the specific conditions desired to promote a desired biological reaction or filtration. Each lane 112 includes a first channel 116, a second channel 118, and a membrane 104 arranged at least partially between them. In some embodiments, the first plate, the second plate and the membrane are simultaneously laser bonded, thereby providing the advantage of forming lanes 112 that are leak proof. The first plate 102 includes an inlet/outlet manifold 110 and the second plate 106 may include an inlet/outlet manifold 114. In some embodiments, the manifolds bifurcate and connect a single input or output for each plate to a plurality of lane inputs or outputs. In operation, the biological source material is introduced into the first channel 116 and is deposited on or captured by the membrane 104. The biological products can then be deposited into and collected from the second channel 118.

In accordance with aspects of the disclosure, the membrane can be configured to selectively capture specific biological source materials or substances to produce desired biological products. For instance, when producing platelets or platelet like cells and/or extracellular vesicles (EVs) from megakaryocytes, the membrane may be configured to selectively capture megakaryocytes and allow the captured megakaryocytes to extend proplatelet extensions through the membrane and to release platelets or platelet like cells and/or extracellular vesicles (EVs) into the second channel. The flow rates in the first channel and the second channel may be adjusted to ensure that the captured biological source material experience desired shear rates, for example, physiological shear rates, to produce biological products. In some embodiments, the present devices may be used as a filter. In such embodiments, the membrane between the first and second channel may be selected to filter out unwanted substances from the composition in the first channel.

In some embodiments, the present disclosure further provides a system and method that allows the first and second plate of the fluidic system to be made of biocompatible versions of the same type of material as the membrane, such as polycarbonate. The laser welded fluidic system has several benefits over previous designs. Because it can contain only a single polymer material, for example, polycarbonate (PC) that makes up the first plate, membrane, and second plate, the opportunity for incompatibilities with chemical or biological processes can be significantly reduced. The elimination of the adhesives and glues can also eliminate volatile organic compounds (VOC's) often used to bond and promote adhesion in these products. These chemicals are reactive and often include gas chemicals that interfere with biological processes or sensors. By eliminating these materials, biological compatibility is maximized while potential for contamination is minimized. FDA verification and validation is also simplified, such as leachables and extractables testing.

The present methods and systems are suitable for use with various biomaterials. In some embodiments, one of the plates can be made of a polymer that is essentially transparent and transmits certain wavelengths of light that can be used for laser welding, and the membrane or the other plate can be made from the same material with added colorants that absorbs the same wavelengths of light. Many polymers are transparent enough to be used in this fashion, such as, for example, Polycarbonate (PC), Acrylin (PMMA), Cyclin Olefin Polymer (COP), Cyclic Olefin Copolymer (COC), Polystyrene and combinations of these materials.

In some embodiments, membranes can be made of other materials such as Cellulose acetate (CA), Nitrocellulose, (CN), Cellulose Esters (CE), Acrylic (PMMA), Polystyrene (PS), Polydimethylsiloxane (PDMS), Polyacrilonitrile, Poly sulphone (PSU), Polyethylene (PE), polyamide, polyimide, Polyethylene (PE), Polytetrafluoroethylene (PTFE) and Polypropylene (PP). In some embodiments, the membrane is a track etch membrane that has consistent sized holes passing from the front of the membrane to the back. This type of membrane allows flow through the membrane but not along the membrane.

In some embodiments, this process can also work with a non-woven membrane. A non-woven material is a mat of randomly oriented fibers that are bonded together to form a plurality of pores. This type of membrane does not have consistent pore size but has many pores.

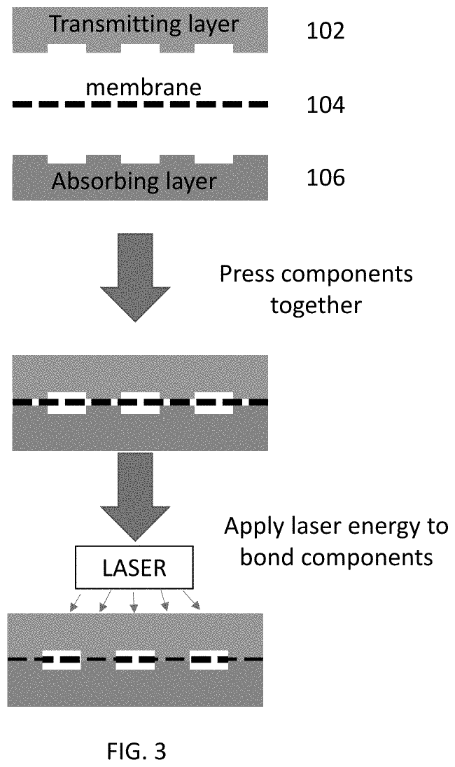

In reference to FIG. 3, a masked laser welding process or contour laser welding can be used to form the fluidic systems of the present disclosure. Such process results in bonding the first plate 102, the second plate 106, and the membrane 104 together into an air and water tight assembly that can be used as a filter, fluidic system, sensing devices or similar applications. To accomplish this, the first plate 102 is configured to transmit the energy from the laser source (also referred to as a transmitting layer) and the second plate 106 is configured to absorb the energy transmitted through the first plate and the membrane (also referred to as an absorbing layer). In operation, the parts are aligned and assembled into a stack with the transmitting layer 102 toward the laser source, the membrane 104 in the middle and the absorbing layer 106 on the bottom. The parts are then exposed to laser energy to be welded. In some embodiments, a line laser can move across the parts while a mask allows light to reach the areas that are to be welded. In some embodiments, contour welding can be used where a laser beam follows a predefined path to bond the parts together in precise locations. In some embodiments, a different welding energy can be used to attach the parts together. It should further be noted that other types of energy can also be used in the method of the present disclosure as long as such energy can be transmitted through the first plate and be absorbed at or in proximity of the bonding areas where the plates need to be bound. In some embodiments, light energy other than laser energy can be used.

The laser light or energy passes through the transmitting layer 102, through the membrane 104 and into the absorbing layer 106. The laser energy absorbed by the absorbing layer 106 heats it up, which heats the membrane 104 and the transmitting layer 102 creating a bond between the transmitting layer 102, membrane 104 and absorbing layer 106. As discussed below, in some embodiments, the membrane 104 can function to absorb light instead of or in addition to the absorbing layer 106.

The laser welded fluidic system targeted at high volume manufacturing is designed to incorporate three-layer laser welding technology with the membrane sandwiched between the upper and lower plates. The joint design, where the assembly is being welded, is largely identical throughout the design having a rib from the upper plate and the lower plate coming together to make contact with the membrane.

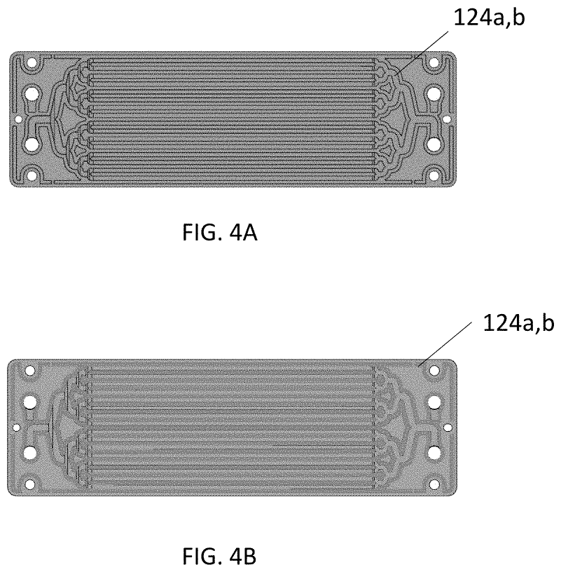

In reference to FIGS. 4A and 4B, ribs 124a, 124b may be provided on the plates to facilitate the connection between the plates. For example, FIG. 4A illustrates an embodiment of a pattern of ribs 124a,b formed on the first plate 102 of the fluidic system 100, such that the welding forms a pattern as shown in FIG. 4B. In some embodiments, the ribs 124a,b are the same width. The width of the ribs 124a,b can vary, but in some embodiments the ribs can be about 2 mm wide. In operation, the optical path of the laser passes through the upper rib 124a and the membrane 104 to be absorbed by the lower rib 124b during laser welding.

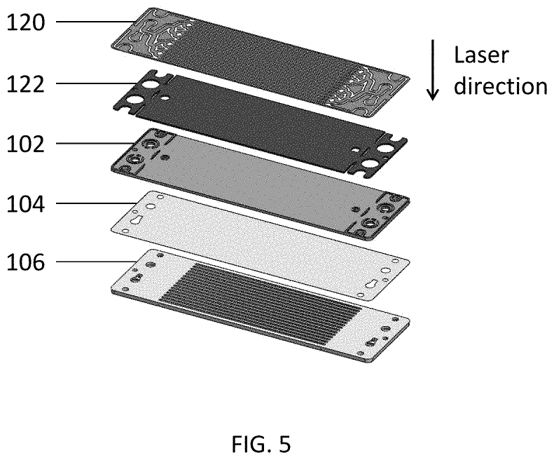

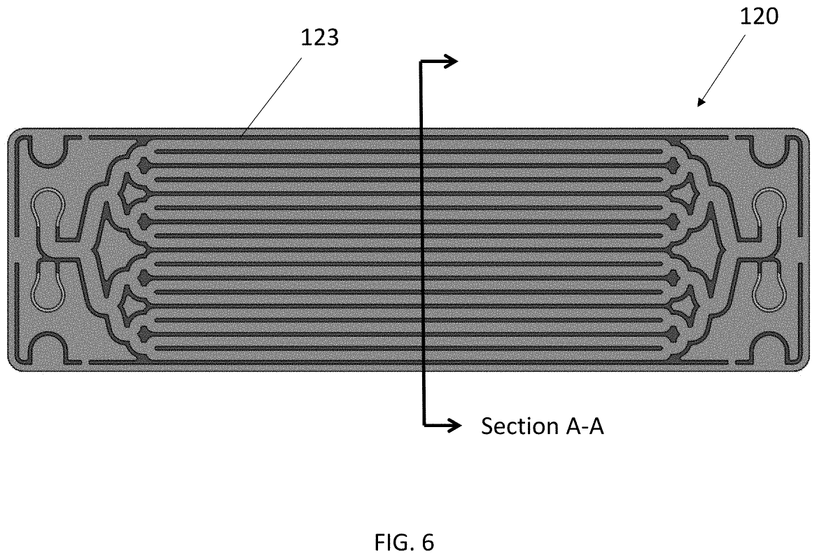

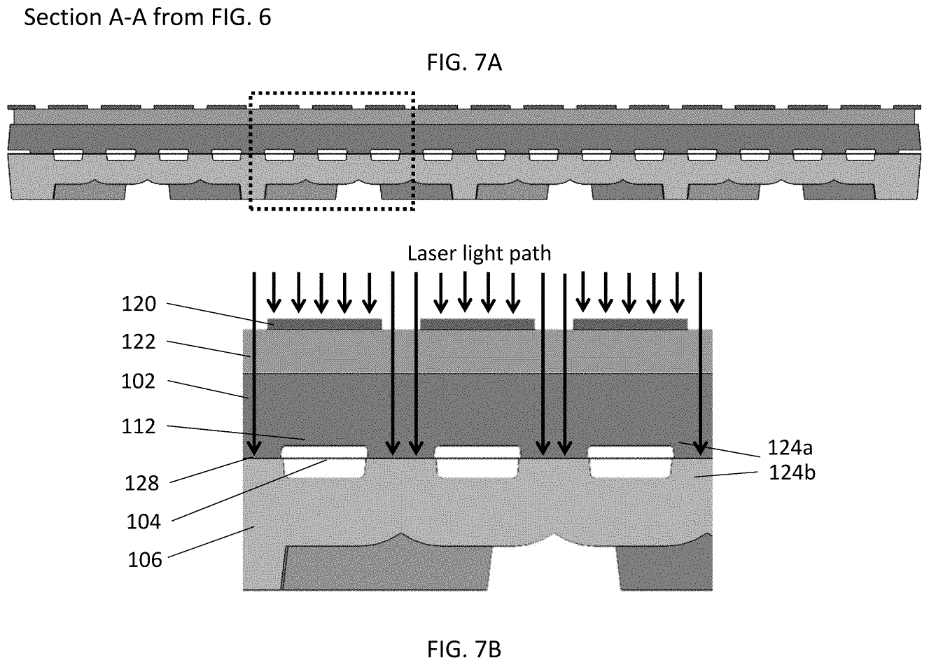

In reference to FIG. 5, a mask 120 may be provided to guide the laser welding. In some embodiments, as shown in FIG. 6, the mask 120 may include a pattern 123 that follows the pattern of the ribs 124a, 124b. In operation, as shown in FIGS. 7A and 7B, the first plate 102 and second plate 106 are welded together with the membrane being part of the weld. The top surface of the first plate can be designed to allow the laser light to reach the joint area without being disrupted by lensing effects. Minor offsets of the generally flat upper surface of the first plate can be used, but slanted or curved sections on the top surface will disrupt the laser path and the welding process.

FIGS. 7A and 7B illustrate an embodiment of a cross-section of a fluidic system 100 showing the layers thereof and the weld area 128 between the first plate 102 and the second plate 106. As shown, the top mask 120 is positioned on an upper surface of the first plate 102 such that laser light can travel through the openings in the top mask through to the light-absorbing second plate 106 of the fluidic system 100. In some embodiments, a spacer plate 122 may be disposed between the mask 120 and the first plate 102. The laser light is effective to laser weld the plates together to form the layered fluidic body 101 with the membrane 104 between the first plate 102 and second plate 106 and having channels 112 formed therethrough.

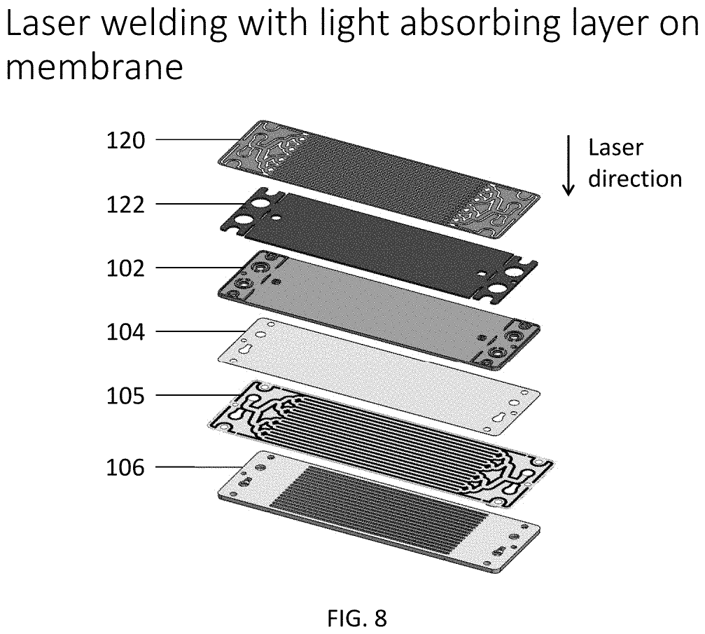

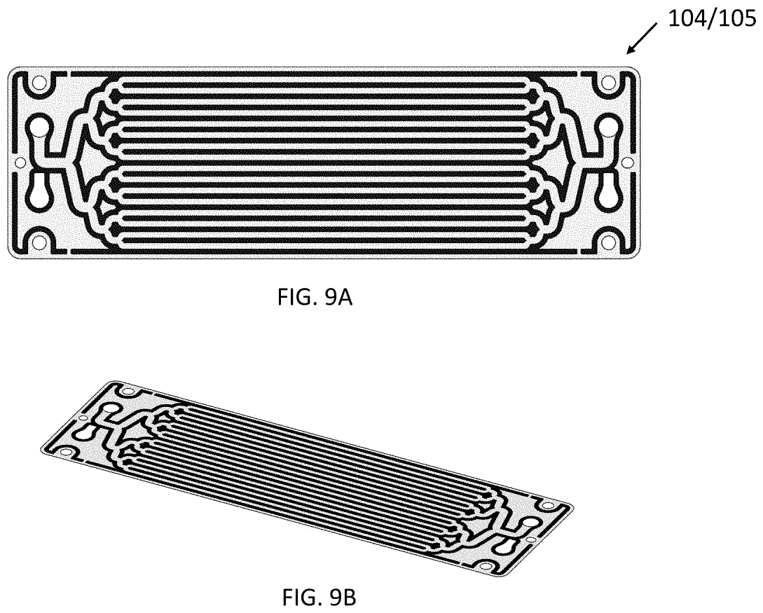

In reference to FIG. 8, in some embodiments, a light absorbing layer 105 can be applied between the membrane 104 and the second plate 106 where a weld is desired. In this manner, the first and second plates may be made of the same, light transmitting material for the ease of manufacture, and a separate light absorbing layer can transfer the second plate into a light absorbing layer. In some embodiments, the second plate 106 may be made of a light absorbing material and the light absorbing layer 105 can be used to enhance the light absorbing characteristics of the second plate 106. In some embodiments, the light absorbing layer 105 may be combined with the membrane 104. As shown in FIGS. 9A and 9B, in some embodiments, the light absorbing layer 105 may include a welding pattern similar to the patterns of the ribs 124a,b.

The light absorbing layer can take many forms, including but not limited to silk screened, printed or otherwise applied to the membrane in the desired pattern. In some embodiments, such pattern may correspond to the pattern of the ribs, as described above, such that the bonding takes place at the ribs of the first plate or the second plate. In this configuration, the first plate and second plate can be transparent or the second plate can also be light absorbing. This embodiment may include an extra step of applying the light absorbing layer to the membrane, which can be accomplished via printing or silk screening. This layer 105 can be applied to the front and/or back of the membrane 104.

In some embodiments, a light absorbing layer can be added to the bottom of the first plate. This layer will then absorb the energy from the laser and heat the membrane and second plate creating a bond and seal.

Because the membrane can be very thin, in some embodiments, the membrane is not heated where it is not sandwiched between the plates. Otherwise, the membrane can deform or melt and deform its pores or possibly create a breach in the membrane web. By creating a mask 120 that is offset from the edge of the unsupported membrane 104, a bond can be created without damaging the membrane 104. For example, the mask 120 can be offset by 0.1-0.5 mm from the edge of the unsupported membrane. In contour welding, the laser beam can be programed to keep the edge of the beam offset from the edge of the unsupported membrane by a similar distance to prevent damaging the membrane.

The membrane can be held flat while it is assembled with the upper and lower plate. Because the membrane is thin and difficult to handle, a method for stretching the membrane slightly without wrinkling it is required. In some embodiments, a card stock frame with adhesive can be mounted to the edge of the membrane in order to allow the membrane to be easily handled and kept flat. In some embodiments, holes in the membrane that are made via laser cutting or die cutting can be used to stretch the membrane over pins. In some embodiments, the pins can be tapered to allow the membrane to be stretched as it is pushed down on the pins. In some embodiments, the process can be performed under vacuum or negative pressure to avoid expansion of gas entrapped within the pores of the membrane from creating cosmetic or functional imperfections as it expands when heated by the laser and subsequently contracts as it cools to room temperature.

As explained above, in some embodiments of a fluidic system, a plurality of channels, or lanes, provide the specific conditions desired to promote the desired biological reaction. Each lane has a first channel and a second channel. The cross section of the channel varies in order to produce the desired fluidic shear on the bottom of the membrane and volumetric flow rate through the membrane. There are output manifolds in the first plate and second plate that bifurcate and connect the output of the lanes with a single output. If these manifold channels were facing each other as the upper channel and lower channel are in the lane, there would be uncontrolled flow through the membrane. In some embodiments, the second plate input and output manifold channels can be moved to the bottom of the second plate. A hole in the plate at the beginning of the lanes allows the liquid to flow from the bottom of the second plate to the lower channel in the lane. The channels on the lower plate are closed by a membrane, optionally of the same material as the plates. In this way the flows in the channels are kept separate until they reach the lane which is designed to create the desired fluidic shear across the bottom of the membrane and volumetric flow through the membrane that promotes the desired biological reaction.

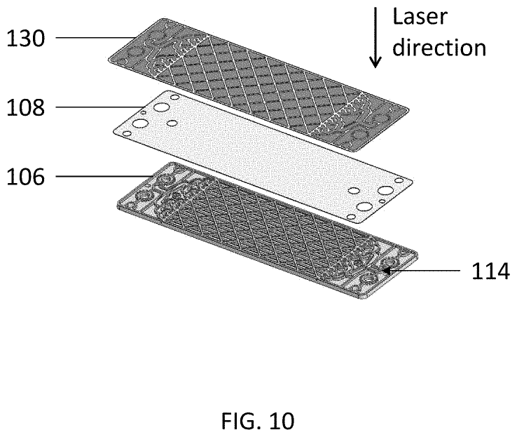

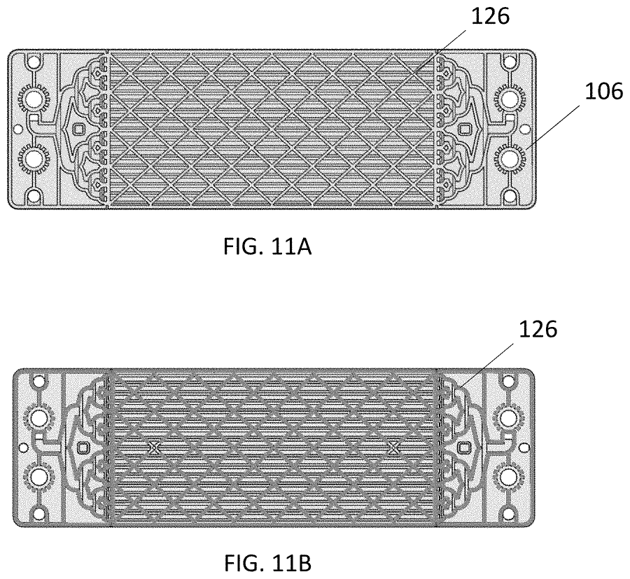

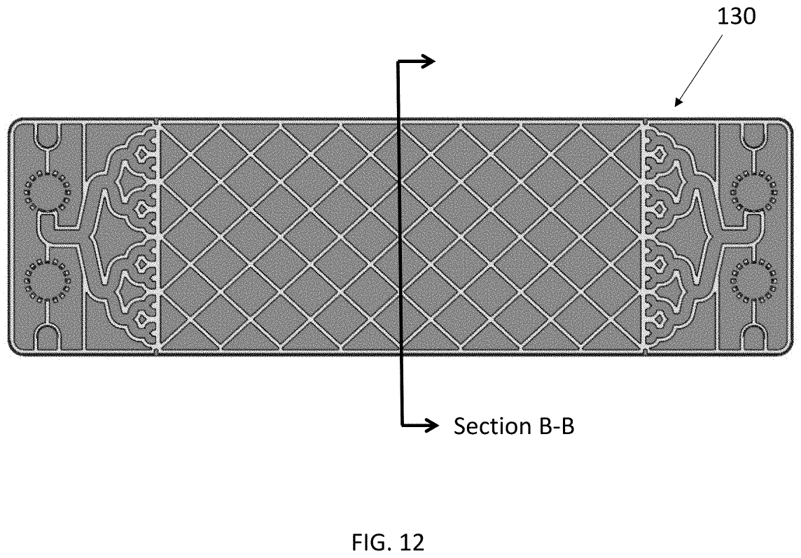

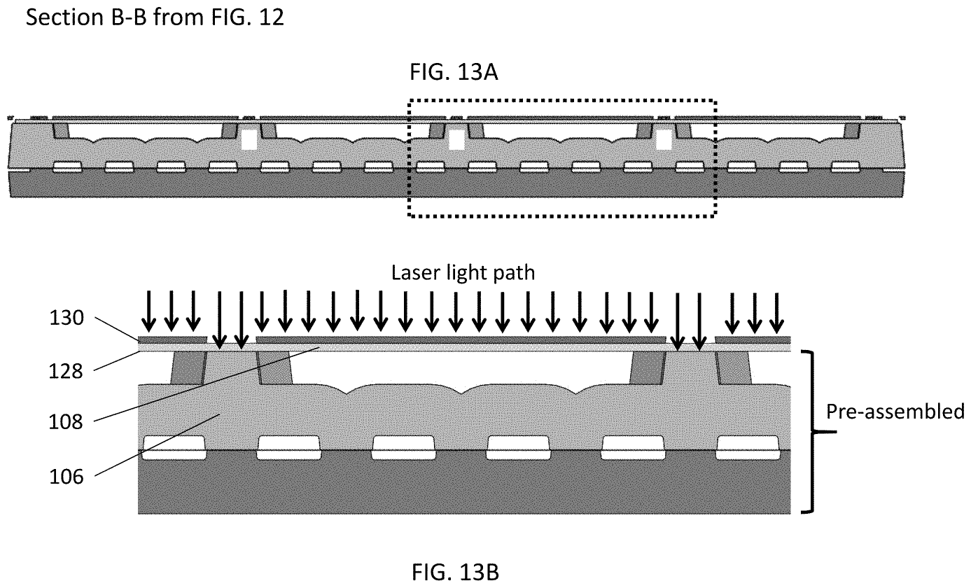

In some embodiments, as shown in FIG. 10, the inlet/outlet manifold 114 is provided on the bottom of the second plate 106 and is formed by attaching a cover film 108 to the bottom of the second plate 106. In some embodiments, to assist in coupling the cover film 108 and the second plate 106, ribs 126 are formed on a bottom surface of the second (lower) plate 106 as shown in FIG. 11A, which provide a welding pattern as shown in FIG. 11B. A bottom mask 130 may be provided that has the same welding patterns as the one formed by the ribs 126, as shown in FIG. 12.

FIGS. 13A and 13B illustrate an embodiment of a cross-section of a fluidic system showing the layers thereof and the weld area between the second plate and the cover film. As shown, the bottom mask 130 is positioned on the cover film 108 such that laser light can travel through the openings in the bottom mask 130 to form a weld area 128 between the second plate 106 and the cover film 108. The laser light is effective to laser weld the ribs formed on the second plate to the cover film to form openings between the bottom surface of the second plate and the cover film to allow fluid flow to the inlet of the lower channels of the fluidic system.

This design allows each layered device to be manufactured without the use of glue or adhesives with all the channels being created by highly accurate injection molding techniques in simple straight-pull molds (molds with single part cavity and core components).

In some embodiments, the instant fluidic system is designed so the membrane layer is flat and continuous in order to easily create a liquid tight seal. Changes in elevation of the membrane will be difficult to seal and hard to reliably manufacture.

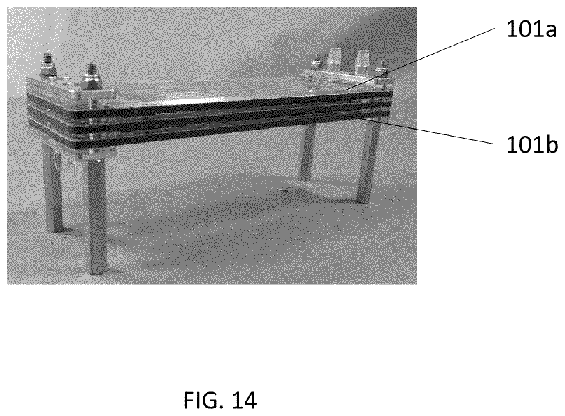

In reference to FIG. 14, in some embodiments, a plurality of the fluidic bodies 101a, 101b as described herein can be used in a stacked configuration. Such stacked bioreactor can provide a number of features and capabilities aimed at generating clinically and commercially relevant biological products from biological source materials. In some embodiments, the system and method described herein may be used to generate high platelet or platelet like cells and/or extracellular vesicles (EVs) yields usable for various clinical applications, such as but not limited to, treating a disease or disorder related to one or more of an immunoinflammatory disorder, a metabolic disorder, neoplastic disorder, autoimmune disorder, liver disease, viral or bacterial-induced diseases or infections or platelet infusion.

The various configurations presented above are merely examples and are in no way meant to limit the scope of this disclosure. Variations of the configurations described herein will be apparent to persons of ordinary skill in the art, such variations being within the intended scope of the present application. In particular, features from one or more of the above-described configurations may be selected to create alternative configurations comprised of a sub-combination of features that may not be explicitly described above. In addition, features from one or more of the above-described configurations may be selected and combined to create alternative configurations comprised of a combination of features which may not be explicitly described above. Features suitable for such combinations and sub-combinations would be readily apparent to persons skilled in the art upon review of the present application as a whole. The subject matter described herein and in the recited claims intends to cover and embrace all suitable changes in technology.

1. A method of making a fluidic system, the method comprising:
assembling a fluidic system comprising a first plate, a second plate and a membrane disposed between the first plate and the second plate;
applying laser energy to the fluidic system to cause the first plate, the second plate and the membrane to heat at bonding areas; and
allowing the bonding areas to cool down such that the first plate, the second plate and the membrane are bonded together.

2. The method of claim 1, wherein the first plate is energy transmitting and the second plate is energy absorbing, such that the second plate absorbs the laser energy to enable the bonding areas to increase temperature due to the absorbed laser energy.

3. The method of claim 1, wherein the membrane includes a light absorbing layer.

4. The method of claim 1, wherein one or more fluid channels are formed in the fluidic system with the membrane being disposed in the one or more fluid channels.

5. The method of claim 4, further comprising disposing a mask on top of the fluidic system, the mask being configured to block the laser energy from portions of the membrane disposed in the one or more fluid channel.

6. The method of claim 4, wherein the first plate and the second plate each include an inlet manifold and outlet manifold to enable fluid flow through one or more fluid channels.

7. The method of claim 6, wherein the inlet manifold and the outlet manifold of the second plate are located on a bottom side of the second plate and are formed by a cover coupled to the bottom side of the second plate.

8. The method of claim 1, wherein the first plate and the second plate include a pattern of ribs that form the bonding areas.

9. The method of claim 1, wherein the method is performed under vacuum or negative pressure to avoid expansion of gas entrapped within one or more pores of the membrane.

10. The method of claim 1, wherein the first plate, the second plate and the membrane are made of a same material.

11. A method of making a fluidic system, the method comprising:
connecting a first plate and a second plater to form a fluidic body, the first plate including a first pattern of ribs and the second plate including a second pattern of ribs corresponding to the first pattern of ribs, such that the first pattern of ribs and the second pattern of ribs are aligned to define a plurality of fluidic lanes through the fluidic body;
disposing a membrane between the first plate and the second plate, the membrane separating each of the plurality of fluidic lanes into a first channel and a second channel; and
applying laser energy to the fluidic body such that the laser energy is transmitted through the first plate and is absorbed by the second plate at the second pattern of ribs to cause the first plate, the second plate and the membrane to weld with one another to fluidically seal the plurality of fluidic lanes.

12. The method of claim 11, further comprising a mask on top of the fluidic system, the mask being configured to block the laser energy from portions of the membrane disposed in the plurality of fluidic lanes.

13. The method of claim 11, wherein the first plate and the second plate each include an inlet manifold and outlet manifold to enable fluid flow through one or more fluid channels.

14. The method of claim 13, wherein the inlet manifold and the outlet manifold of the second plate are located on a bottom side of the second plate and are formed by a cover coupled to the bottom side of the second plate.

15. The method of claim 11, wherein the method is performed under vacuum or negative pressure to avoid expansion of gas entrapped within one or more pores of the membrane.

16. The method of claim 11, wherein the first plate, the second plate and the membrane are made of a same material.

17. The method of claim 16, wherein the membrane includes a light absorbing layer.

18. A fluidic system comprising:
a first plate configured to transmit light;
a second plate configured to absorb light; and
a membrane positioned between the first plate and the second plate,
wherein the first plate, the second plate and the membraned are laser bonded together at a preselected pattern of bonding areas such that one or more fluid channels are formed in the fluidic system with the membrane being disposed in the one or more fluid channels.

19. The fluidic system of claim 18, wherein the first plate, the second plate and the membrane are made of a same material.

20. The fluidic system of claim 18, wherein the first plate includes a first pattern of ribs and the second plate includes a second pattern of ribs corresponding to the first pattern of ribs, wherein the first pattern of ribs connects to the second pattern of ribs to form the bonding areas.

21. The fluidic system of claim 18, wherein the first plate and the second plate each include an inlet manifold and outlet manifold to enable fluid flow through one or more fluid channels.

22. The fluidic system of claim 21, wherein the inlet manifold and the outlet manifold of the second plate are located on a bottom side of the second plate and are formed by a cover coupled to the bottom side of the second plate.
